(19) United States
(12) Patent Application Publication
(10) Pub. No.: US 2002/0089331 A1
(43) Pub. Date: Jul. 11, 2002

(54) Test lead for cathode ray tube aging line socket and method of making and using same

(75) Inventors: Brian Solomich, Vista, CA (US); David Allen Murtishaw, Sun City, CA (US); Edward Martinez, Vista, CA (US)

Correspondence Address: STEVEN L. NICHOLS, RADER, FISHMAN & GRAVER PLLC, 10653 S. RIVER FRONT PARKWAY, SUITE 150, SOUTH JORDAN, UT, 84095, US

(73) Assignee: Sony Corporation

(21) Appl. No.: 09/756,816

(22) Filed: Jan. 9, 2001

(51) Int. Cl. G01R 31/00

(52) U.S. Cl. 324/413

(57) ABSTRACT

A novel test lead can be used to connect an aging line with a voltage or multi-meter in order to monitor the voltage output by the aging line. The aging line is used to age electronic devices and components, particularly cathode ray tubes, during the manufacturing process. The test lead includes a plug adapted for ready connection to an output socket of the aging line without requiring any disassembly of the socket. The other end of the test lead preferably includes a number of clips, banana or alligator, for connecting the lead to the voltage or multi-meter. In this way, the output voltage of the aging line can be easily and rapidly tested for conformance with predetermined specifications.

### FIELD OF THE INVENTION

The present invention relates to the field of manufacturing cathode ray tubes. More particularly, the present invention relates to the practice of aging the components of a cathode ray tube during manufacture to overcome or discover initial faults or fluctuations in those components. Specifically, the present invention provides a novel test lead for monitoring the voltage output of an aging line used in the aging process.

### BACKGROUND OF THE INVENTION

Cathode ray tubes or CRTs are used in most television sets and computer monitors. The CRT provides the screen on which the display of the television set or monitor is generated.

As shown in FIG. 1, a conventional CRT (102) has a flat portion (106) that forms the screen of the television set or monitor into which the CRT (102) is incorporated. Phosphor, a material that emits light when struck by an electron beam, is coated over the screen portion (106) of the CRT (102).

An electron gun (104) is provided in the neck of the CRT (102). A stream of electrons emitted from the electron gun (104) is scanned over the phosphor and turned on and off during the scanning to cause the phosphor to glow in certain places and not others. In very simple terms, this is how an image is generated on the screen of a television or video monitor.

A yoke (103) is provided around the neck of the CRT (102). This yoke (103) produces a changing magnetic field through with the electron beam from the electron gun (104) passes. The electron beam is deflected by the magnetic field of the yoke (103). Consequently, by varying the magnetic field created by the yoke (103) in a precise cycle, the electron beam can be scanned, line-by-line, over the entire surface of the screen (106) to generate video images thereon.

In the electronic and electric industries, it is a normal part of the manufacturing process to subject electronic parts or electric products to an aging process. The aging process usually includes providing power to the electronic components of an electronic device. This is done to identify faulty components and also to reduce initial faults or fluctuations in the component's performance characteristics that frequently occur when a component is first placed in service, but disappear when the component has aged.

In the manufacture of cathode ray tubes, the tube (or the television or monitor into which it is incorporated) is preferably subjected to an aging process. This would typically include maintaining the CRT display in an “ON” condition at a predetermined temperature for a given period, e.g. several hours. Usually, this aging process is performed downstream of the assembly section in a production line. The aging section of the production line may be formed by surrounding a conveyor line by partitions and providing an inlet and outlet to define an aging room. The conveyor line in the aging room is driven at a predetermined speed that is set so as to transfer the television receiver from the inlet to the outlet in the predetermined aging period.

During the aging process, the CRT (102) must be connected to a power supply (101) with what is called an aging line (105). The aging line (105) includes a socket (107) that receives a plug (not shown) on the CRT (102). Through this connection, the aging line (105) supplies a voltage to the CRT (102) so that the CRT (102) can be turned on and operated during the aging process. The aging line (105) may also include carrier circuitry for providing appropriate signals for aging the CRT (102).

It is important to the aging process that the aging line (105) supply a voltage to the CRT (102) that is within predetermined specifications. The voltage provided to the CRT (102) by the aging line (105) will not be the same voltage output by the power supply (101) due to the resistance of the aging line, and any aging carrier circuitry connected thereto. Consequently, the aging line (105) must be calibrated when it is first placed in service and tested periodically thereafter to ensure that the voltage supplied is within the appropriate range for the aging process.

Conventionally, testing the voltage output of the aging line (105) has involved disassembling the socket (107). With the socket (107) opened, the leads in the socket (107) can be tested using, for example, probe or alligator clip test leads and a voltage or multi-meter.

However, this process is obviously time-consuming and involves the difficulties of opening and reassembling the socket (107) of the aging line (105) in order to test the voltage supplied. Moreover, it can be dangerous for a technician to open the socket (107). The technician runs the risk of receiving an electric shock if the socket (107) is not opened properly and with care. Consequently, there is a need in the art for an improved means of monitoring the voltage supplied by an aging line used in the aging process of CRT manufacture.

### SUMMARY OF THE INVENTION

The present invention meets the above-described needs and others. Specifically, the present invention provides an improved means of monitoring the voltage supplied by an aging line used in the aging process of CRT manufacture. The method of the present invention allows a technician to quickly determine the voltage supplied by an aging line so that there is no need to interrupt the production line while the aging line is disassembled and tested.

Additional advantages and novel features of the invention will be set forth in the description which follows or may be learned by those skilled in the art through reading these materials or practicing the invention. The advantages of the invention may be achieved through the means recited in the attached claims.

In summary, the present invention may be embodied and described as a test lead for determining the voltage output by an aging line in a system for aging electronic devices and components, particularly CRTs. The test lead is used to connect the aging line to a voltage meter. In a preferred embodiment, the test lead includes a plug that is received in and electrically connected with a socket of the aging line; and an output, connected to the plug, for electrically connecting the plug to the voltage meter.

Preferably, the plug includes a number of pins arranged in accordance with corresponding pin receptacles in the socket of the aging line. The output may include a number of clips for connection to the voltage meter. These clips may be, for example, banana clips, alligator clips or the like.

Regardless of the type of clip used, each clip is preferably connected to a respective pin on the plug. A cladding may also be provided for containing the wires connecting the clips of the output and the pins of the plug.

The present invention also encompasses the methods of making and using the test lead described above. Specifically, the present invention encompasses a method of monitoring the voltage output by an aging line by connecting a socket of the aging line with a voltage meter using a test lead that includes a plug that is received in and electrically connected with the socket of the aging line; and an output, connected to the plug, for electrically connecting the plug to the voltage meter. This method may also include: providing a plurality of pins on the plug, the pins being arranged in accordance with corresponding pin receptacles of the socket of the aging line; and providing a number of banana or alligator clips as the output of the test lead.

The present invention also encompasses a method of making a test lead for determining the voltage output by an aging line by connecting the aging line to a voltage meter. This method preferably includes forming a plug that is received in and electrically connected with a socket of the aging line; and forming an output, connected to the plug, for electrically connecting the plug to the voltage meter.

This method may also include forming a number of pins on the plug, the pins being arranged in accordance with corresponding pin receptacles of the socket of the aging line. As above, a number of banana or alligator clips may be provided as the output.

This method may also include providing, as the output, a plurality of clips for connecting to the voltage meter; and electrically connecting each clip to a respective pin on the plug. Finally, this method may include wrapping a cladding around wires connecting the clips of the output and the pins of the plug.

### BRIEF DESCRIPTION OF THE DRAWINGS

The accompanying drawings illustrate the present invention and are a part of the specification. Together with the following description, the drawings demonstrate and explain the principles of the present invention.

FIG. 1 is an illustration of a conventional CRT and an apparatus for aging the CRT during the manufacturing process.

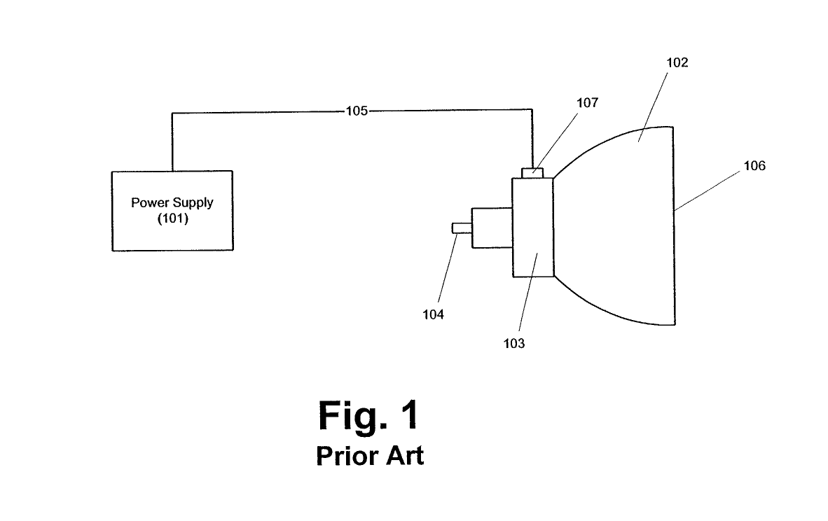

FIG. 2 is an illustration of a method according to the present invention for monitoring the voltage output of an aging line used to age CRTs during the manufacturing process.

FIG. 3 is a detailed illustration of a test lead according to the present invention that is used in the monitoring method illustrated in FIG. 2.

FIG. 4 is a detailed illustration of a plug of the test lead illustrated in FIG. 3.

### DETAILED DESCRIPTION OF THE PREFERRED EMBODIMENTS

The present invention provides a novel test lead which can be used to connect the socket of an aging line for aging a Cathode Ray Tube (“CRT”) with a voltage or multi-meter for monitoring the voltage output of the aging line.

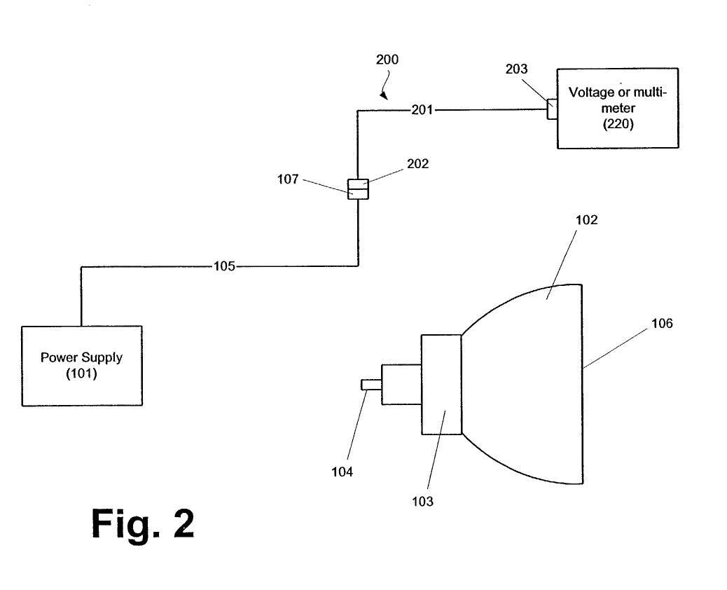

Using the drawings, the preferred embodiments of the present invention will now be explained. As shown in FIG. 2, the present invention provides a method of monitoring the voltage output of an aging line (105) without requiring any disassembly of the socket (107) of the aging line (105). This method includes providing a novel test lead (200) which can be used to connect the socket (107) of the aging line (105) with a voltage or multi-meter (220) for monitoring the voltage output of the aging line (105).

Under the principles of the present invention, a novel test lead (200) is provided which, at one end, has a plug (202). This plug (202) matches the configuration of the plug portion of the CRT (102) to which the aging line (105) is connected when providing power to the CRT (102) for the aging process. Consequently, this plug (202) can be connected to the socket (107) of the aging line (105) without any disassembly of the aging line (105) or its socket (107).

The plug (202) of the lead (200) is wired (201) to a voltage or multi-meter (220). The meter (202) that consequently can be used to measure the voltage output by the aging line (105) via the connection (201) with the plug (202) inserted in the socket (107) of the aging line (105). The plug (202) can be wired directly into a meter (220), or may incorporate a plug or socket (203) of any type necessary to readily connect to a particular meter (220).

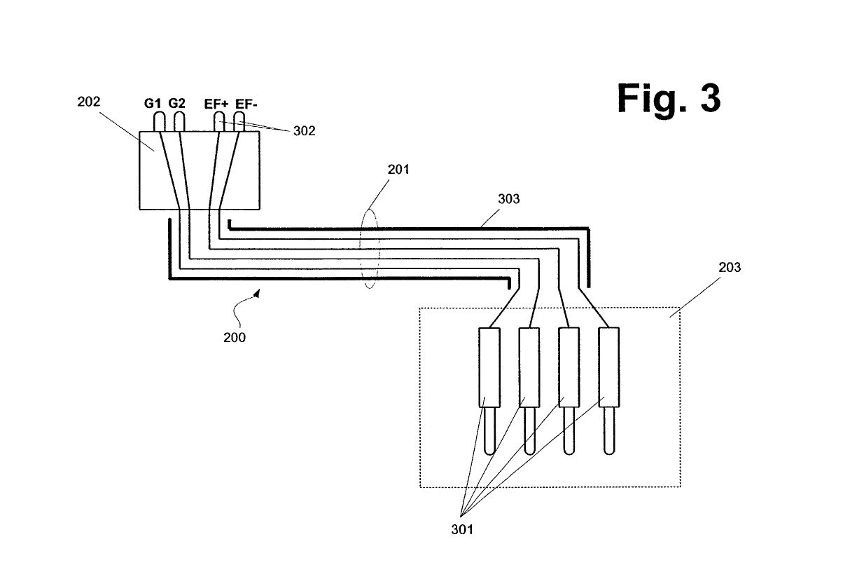

FIG. 3 provides a more detailed illustration of the test lead (200) of the present invention. As shown in FIG. 3, the plug (202) of the test lead (200) may include a number of pins (302) that are arranged in a configuration to mate with the socket (107) of the aging line (105). As will be appreciated by those skilled in the art, the pins (302) of the plug (202) can be disposed in any configuration necessary to mate with the corresponding receptacles in the socket (107) and contact the corresponding individual wires within the aging line (105).

At the other end of the test lead (200), the connection (203) for the meter (220) is preferably a number of banana plugs (301). Banana plugs such as those illustrated are traditionally used to connected test leads to a voltage or multi-meter (220). In fact, most conventional multi-meters, such as those manufactured by Fluke® Corp., will include sockets for receiving banana plugs. Consequently, by incorporating banana plugs into the test lead (200) of the present invention, it becomes very easy to connect the lead (200) to a meter (220) for monitoring the voltage output by the aging line (105). Alternatively, the banana plugs (301) could also be replaced by alligator clips that are also traditionally used to connect test leads to meters.

As illustrated in FIG. 3, each pin (302) on the plug (202) may be connected to a specific banana clip (301). A cladding (303) may be used to contain all the wires of the connection (201) that run between the pins (302) and the clips (301).

In this way, the cladding (303) unifies the lead (200) and provides, in essence, a single cable between the plug (202) and the banana clip cluster (301).

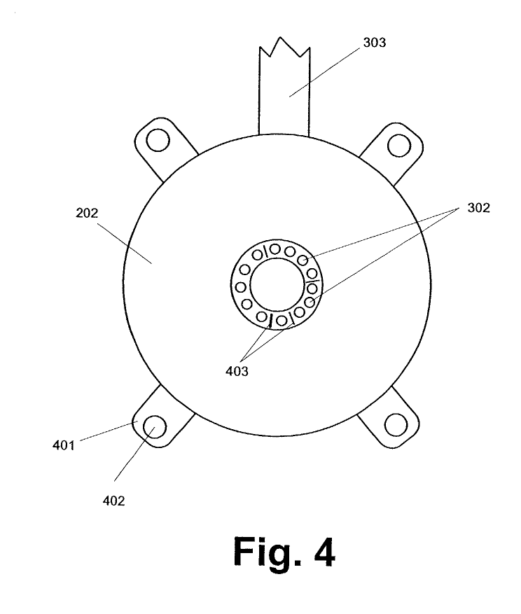

FIG. 4 illustrates a specific embodiment of the plug (202) of the test lead (200) of the present invention. As shown in FIG. 4, the plug (202) may include a number of pins (302) for mating with the corresponding receptacles in the socket (107) of the aging line (105). These plugs (202) may be arranged in a circular fashion, as shown, concentric with the center of the plug (202).

Ridges (403) or dividers may be provided between some of the pins (302) on the plug (202) in order to minimize arcing between pins (302). Additionally, a number of tabs (401) may be provided around the perimeter of the plug (202). These tabs (401) may be helpful in connecting the plug (202) with the socket (107) of the aging line (105). In fact, the tabs (401) may include holes (402) through which a screw or other fastener can be placed to secure the plug (202) to the socket (107) when the test lead (200) is in use.

The preceding description has been presented only to illustrate and describe the invention. It is not intended to be exhaustive or to limit the invention to any precise form disclosed. Many modifications and variations are possible in light of the above teaching.

The preferred embodiment was chosen and described in order to best explain the principles of the invention and its practical application. The preceding description is intended to enable others skilled in the art to best utilize the invention in various embodiments and with various modifications as are suited to the particular use contemplated. It is intended that the scope of the invention be defined by the following claims.

What is claimed is:

1. A test lead for determining a voltage output by an aging line by connecting said aging line to a voltage meter, said test lead comprising:
a plug that is received in and electrically connected with a socket of said aging line; and
an output, connected to said plug, for electrically connecting said plug to said voltage meter.

2. The lead of claim 1, wherein said plug further comprises a plurality of pins arranged in accordance with corresponding pin receptacles of said socket of said aging line.

3. The lead of claim 1, wherein said output comprises a plurality of banana clips

4. The lead of claim 1, wherein said output comprises a plurality of alligator clips.

5. The lead of claim 2, wherein said output comprises a plurality of clips for connecting to said voltage meter, each clip being connected to a respective pin on said plug.

6. The lead of claim 5, further comprising a cladding for containing wires connecting said clips of said output and said pins of said plug.

7. A method of monitoring a voltage output by an aging line, said method comprising connecting a socket of said aging line with a voltage meter using a test lead, said test lead comprising:
a plug that is received in and electrically connected with said socket of said aging line; and
an output, connected to said plug, for electrically connecting said plug to said voltage meter.

8. The method of claim 7, further comprising providing a plurality of pins on said plug, said pins being arranged in accordance with corresponding pin receptacles of said socket of said aging line.

9. The method of claim 7, further comprising providing a plurality of banana clips as said output of said test lead.

10. The method of claim 7, further comprising providing a plurality of alligator clips as said output of said test lead.

11. A method of making a test lead f or determining a voltage output by an aging line by connecting said aging line to a voltage meter, said method comprising:
forming a plug that is received in and electrically connected with a socket of said aging line; and
forming an output, connected to said plug, for electrically connecting said plug to said voltage meter.

12. The method of claim 11, further comprising forming a plurality of pins on said plug arranged in accordance with corresponding pin receptacles of said socket of said aging line.

13. The method of claim 11, further comprising providing a plurality of banana clips as said output.

14. The method of claim 11, further comprising providing a plurality of alligator clips as said output.

15. The method of claim 12, further comprising:
providing, as said output, a plurality of clips for connecting to said voltage meter; and
electrically connecting each clip to a respective pin on said plug.

16. The method of claim 15, further comprising wrapping a cladding around wires connecting said clips of said output and said pins of said plug.

17. A test lead for determining a voltage output by an aging line by connecting said aging line to a voltage meter, said test lead comprising:
first means for electrically connecting said test lead with a socket of said aging line; and
second means for electrically connecting said test lead and said socket of said aging line with said voltage meter.

18. The lead of claim 17, wherein said first means further comprise a plurality of pins arranged in accordance with corresponding pin receptacles of said socket of said aging line.

19. The lead of claim 17, wherein said second means comprise a plurality of banana clips

20. The lead of claim 17, wherein said second means comprise a plurality of alligator clips.

21. The lead of claim 18, wherein said second means comprise a plurality of clips for connecting to said voltage meter, each clip being connected to a respective pin on said first means.
